(19) United States
(12) Patent Application Publication
(10) Pub. No.: US 2026/0107470 A1
(43) Pub. Date: Apr. 16, 2026

(54) MEMORY DEVICE HAVING PASS TRANSISTOR CIRCUIT

(71) Applicant: SK hynix Inc., Icheon-si (KR)

(72) Inventors: Jun Youp KIM, Icheon-si (KR); Jin Ho KIM, Icheon-si (KR)

(21) Appl. No.: 19/052,907

(22) Filed: Feb. 13, 2025

(30) Foreign Application Priority Data
Oct. 10, 2024 (KR) 10-2024-0137829

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A memory device having a substrate with an H-shaped active region that includes: a common active region extending in a first horizontal direction and first, second, third and fourth protruding active regions extending from edges of the common active region in a second horizontal direction perpendicular to the first horizontal direction; a first pass transistor having a first gate electrode that is disposed over the first protruding active region; a second pass transistor having a second gate electrode that is disposed over the second protruding active region; a third pass transistor having a third gate electrode that is disposed over the third protruding active region; and a fourth pass transistor having a fourth gate electrode that is disposed over the fourth protruding active region.

### CROSS-REFERENCE TO RELATED APPLICATION

The present application claims the benefit of priority under 35 U.S.C. § 119(a) to Korean Patent Application No. 10-2024-0137829 filed in the Korean Intellectual Property Office on Oct. 10, 2024, which is incorporated herein by reference in its entirety.

### BACKGROUND

### 1. Technical Field

Embodiments of the present disclosure generally relate to a memory device having a pass transistor circuit.

### 2. Related Art

Memory devices may be classified into volatile memory devices and nonvolatile memory devices. Nonvolatile memory devices include, for example, a flash memory device, a resistive memory device such as ReRAM (resistive RAM), PRAM (phase change RAM), MRAM (magnetic RAM), etc. A memory device includes a memory cell array and a pass transistor circuit that transmits operating voltages to word lines of the memory cell array.

### SUMMARY

In an embodiment, a memory device may include: a substrate defined with an H-shaped active region including a common active region that extends in a first horizontal direction and first, second, third and fourth protruding active regions that extend from edges of the common active region in a second horizontal direction perpendicular to the first horizontal direction; a first pass transistor having a first gate electrode that is disposed over the first protruding active region; a second pass transistor having a second gate electrode that is disposed over the second protruding active region; a third pass transistor having a third gate electrode that is disposed over the third protruding active region; and a fourth pass transistor having a fourth gate electrode that is disposed over the fourth protruding active region.

In an embodiment, a memory device may include: a plurality of memory blocks arranged in a first horizontal direction; a substrate defined with an H-shaped active region including a common active region that extends in the first horizontal direction and first, second, third and fourth protruding active regions that extend from edges of the common active region in a second horizontal direction perpendicular to the first horizontal direction; a first pass transistor having a first gate electrode that is disposed over the first protruding active region; a second pass transistor having a second gate electrode that is disposed over the second protruding active region; a third pass transistor having a third gate electrode that is disposed over the third protruding active region; and a fourth pass transistor having a fourth gate electrode that is disposed over the fourth protruding active region.

In an embodiment, a memory device may include: a plurality of memory blocks arranged in a first horizontal direction; a substrate defined with an H-shaped active region including a common active region that extends in a second horizontal direction perpendicular to the first horizontal direction and first, second, third and fourth protruding active regions that extend from edges of the common active region in the first horizontal direction; a first pass transistor having a first gate electrode that is disposed over the first protruding active region; a second pass transistor having a second gate electrode that is disposed over the second protruding active region; a third pass transistor having a third gate electrode that is disposed over the third protruding active region; and a fourth pass transistor having a fourth gate electrode that is disposed over the fourth protruding active region.

### BRIEF DESCRIPTION OF THE DRAWINGS

FIG. 1 is a block diagram of a memory device according to an embodiment of the present disclosure.

FIG. 2 is a view schematically illustrating a memory device according to an embodiment of the present disclosure.

FIG. 3 is a cross-sectional view illustrating a part of a memory cell array of FIG. 1 according to an embodiment of the present disclosure.

FIG. 4 is a diagram illustrating a row decoder according to an embodiment of the present disclosure.

FIG. 5 is a plan view illustrating first, second, third and fourth pass transistors according to an embodiment of the present disclosure.

FIG. 6 is a cross-sectional view taken along a line A-A′ of FIG. 5 according to an embodiment of the present disclosure.

FIG. 7 is a cross-sectional view taken along a line B-B′ of FIG. 5 according to an embodiment of the present disclosure.

FIG. 8 is a plan view illustrating first, second, third and fourth pass transistors according to an embodiment of the present disclosure.

FIGS. 9 and 10 are plan views each illustrating first, second, third and fourth memory blocks and a part of a pass transistor circuit according to each of embodiments of the present disclosure.

FIGS. 11 to 13 are views illustrating effects of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other, or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

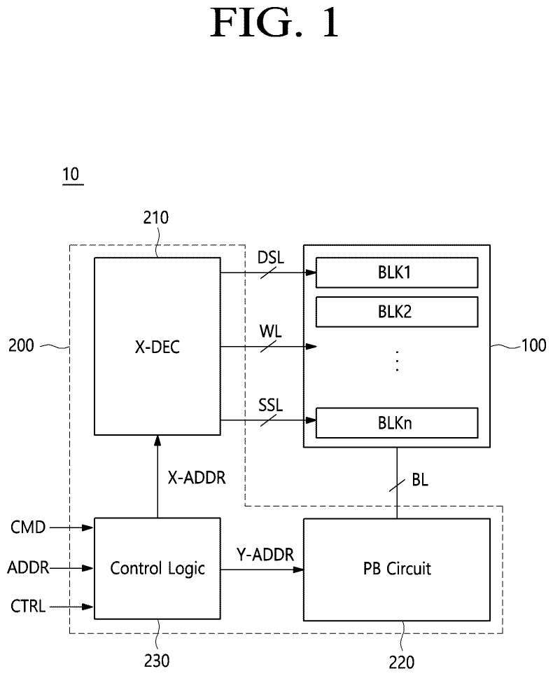

FIG. 1 is a block diagram of a memory device according to an embodiment of the present disclosure.

Referring to FIG. 1, a memory device 10 may include a memory cell array 100 and a peripheral circuit 200. The peripheral circuit 200 may include a row decoder (X-DEC) 210, a page buffer (PB) circuit 220 and a control logic 230. Although not illustrated, the peripheral circuit 200 may further include a voltage generator, a data input/output circuit, a command decoder, an address decoder, and so on.

The memory cell array 100 may include a plurality of memory blocks BLK1 to BLKn. Each of the memory blocks BLK1 to BLKn may include a plurality of memory cells. Each memory cell may be, for example, a flash memory cell. Hereafter, description will be made on the assumption that each memory cell is a NAND flash memory cell, but the present disclosure is not limited thereto. Each memory cell may be a resistive memory cell such as ReRAM, PRAM or MRAM.

The memory cell array 100 may be connected to the row decoder (X-DEC) 210 through a plurality of row lines. The row lines may include source select lines SSL, word lines WL and drain select lines DSL. The memory cell array 100 may be connected to the page buffer (PB) circuit 220 through a plurality of bit lines BL.

The row decoder (X-DEC) 210 may select one among the memory blocks BLK1 to BLKn included in the memory cell array 100, in response to a row address X_ADDR provided from the control logic 230. The row decoder (X-DEC) 210 may transmit operating voltages provided from the voltage generator (not illustrated) to row lines DSL, WL and SSL that are connected to a selected memory block. In order to transmit operating voltages to the row lines DSL, WL and SSL, the row decoder (X-DEC) 210 may include a plurality of pass transistors that are connected to the row lines DSL, WL and SSL.

The page buffer (PB) circuit 220 may select some of the bit lines BL in response to a column address Y-ADDR. The page buffer (PB) circuit 220 may operate as a write driver or a sense amplifier depending on an operation mode.

The control logic 230 may generally control various operations within the memory device 10. The control logic 230 may receive a command CMD, an address ADDR and a control signal CTRL from a memory controller (not illustrated), and on the basis of the received command CMD, address ADDR and control signal CTRL, may generate various control signals for storing data to the memory cell array 100, reading data from the memory cell array 100 or erasing data stored in the memory cell array 100. The control logic 230 may output the row address X-ADDR and the column address Y-ADDR.

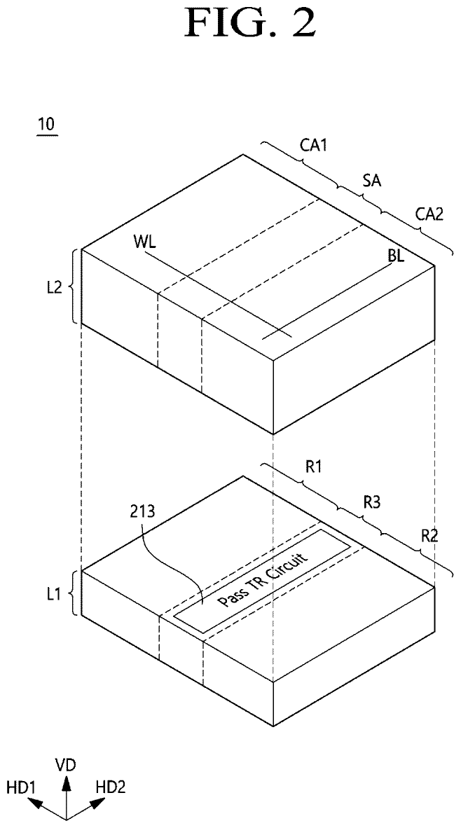

FIG. 2 is a view schematically illustrating a memory device according to an embodiment of the present disclosure.

Referring to FIG. 2, a memory device 10 may include a first semiconductor layer L1 and a second semiconductor layer L2. The first semiconductor layer L1 and the second semiconductor layer L2 may overlap each other in a vertical direction VD. In FIG. 2, the first semiconductor layer L1 and the second semiconductor layer L2 are spaced apart from each other in the vertical direction VD, but this is for the purpose of facilitating understanding. It is to be understood that the upper surface of the first semiconductor layer L1 and the lower surface of the second semiconductor layer L2 are in contact with each other.

In an embodiment, a peripheral circuit (see 200 of FIG. 1) may be disposed in the first semiconductor layer L1, and a memory cell array (see 100 of FIG. 1) may be disposed in the second semiconductor layer L2.

In an embodiment, in the second semiconductor layer L2, a plurality of word lines WL may extend in a first horizontal direction HD1, and a plurality of bit lines BL may extend in a second horizontal direction HD2. Although not illustrated, source select lines and drain select lines may extend in the first horizontal direction HD1. The first horizontal direction HD1 and the second horizontal direction HD2 may vertically intersect each other.

The second semiconductor layer L2 may include a first cell area CA1, a second cell area CA2 and a slimming area SA. In an embodiment, the first cell area CA1 and the second cell area CA2 may be spaced apart from each other in the first horizontal direction HD1, and the slimming area SA may be disposed between the first cell area CA1 and the second cell area CA2.

Although not illustrated, as source select lines, word lines WL and drain select lines are stacked in the vertical direction VD in the first and second cell areas CA1 and CA2 and the slimming area SA, a stack may be configured. The word lines WL may be coupled to cell plugs that pass through the stack in the vertical direction VD, to configure memory cells that are three-dimensionally arranged. The plurality of word lines WL may be implemented in a stairway shape in the slimming area SA.

The first semiconductor layer L1 may include a substrate, and by forming, on the substrate, semiconductor elements such as transistors and patterns for wiring the semiconductor elements, a peripheral circuit (see 200 of FIG. 1) may be configured.

The first semiconductor layer L1 may include a first region R1 that overlaps the first cell area CA1 in the vertical direction VD, a second region R2 that overlaps the second cell area CA2 in the vertical direction VD, and a third region R3 that overlaps the slimming area SA in the vertical direction VD. In an embodiment, a pass transistor circuit 213 is disposed in, but is not limited to, the third region R3.

The first semiconductor layer L1 and the second semiconductor layer L2 may be fabricated on a single wafer. After the first semiconductor layer L1 is formed first, the second semiconductor layer L2 may be built up on the first semiconductor layer L1. In this case, the memory device 10 may has a peripheral under cell (PUC) structure.

On the other hand, the first semiconductor layer L1 and the second semiconductor layer L2 may be ones that are fabricated on different wafers and then are coupled to each other by a wafer bonding technique, where the memory device 10 may has a peripheral over cell (POC) structure.

The memory device 10 according to the present disclosure may be provided as the PUC structure or the POC structure. Meanwhile, although not illustrated, the memory cell array (see 100 of FIG. 1) and the peripheral circuit (see 200 of FIG. 1) may be planarly disposed on a single substrate.

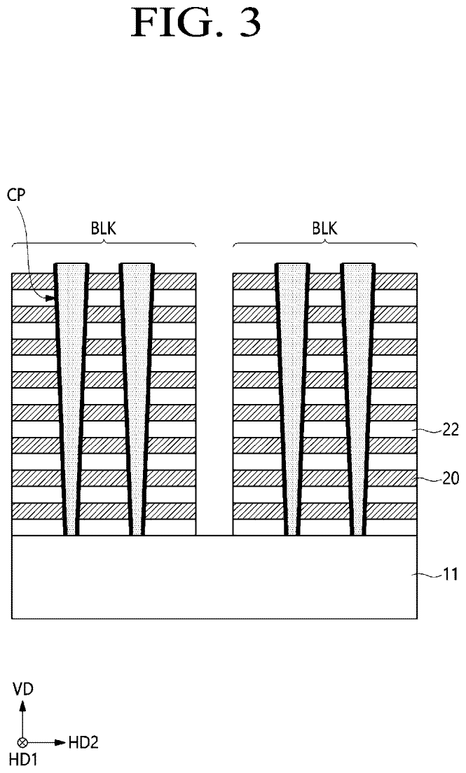

FIG. 3 is a view illustrating a part of a memory cell array of FIG. 1 according to an embodiment of the present disclosure.

Referring to FIG. 3, the memory cell array may include a plurality of memory blocks BLK that are disposed on a source plate 11. The memory blocks BLK may be arranged in the second horizontal direction HD2.

Each memory block BLK may include a plurality of electrode layers 20 and a plurality of interlayer insulating layers 22 that are alternately stacked in the vertical direction VD. The electrode layers 20 may include a conductive material. For example, the electrode layers 20 may include tungsten (W). The interlayer insulating layers 22 may, for example, include silicon oxide.

Among the electrode layers 20, at least one electrode layer 20 from the lowermost electrode layer 20 may configure a source select line, and at least one electrode layer 20 from the uppermost electrode layer 20 may configure a drain select line. The electrode layers 20 between the source select line and the drain select line may configure word lines.

Cell plugs CP may pass through the plurality of electrode layers 20 and the plurality of interlayer insulating layers 22 in the vertical direction VD to extend to the source plate 11. Each cell plug CP may include a channel layer and a cell gate insulating layer. The cell gate insulating layer may have the shape of a straw or a cylindrical shell that surrounds the outer wall of the channel layer. The cell gate insulating layer may include a tunnel insulating layer, a charge storage layer and a blocking layer that are sequentially stacked from the outer wall of the channel layer. In some embodiments, the cell gate insulating layer may have an ONO (oxide-nitride-oxide) stack structure in that an oxide layer, a nitride layer and an oxide layer are sequentially stacked. Memory cells may be configured in the area where the word lines surround the cell plug CP. A source select transistor may be configured in the area where the source select line surrounds the cell plug CP. A drain select transistor may be configured in the area where the drain select line surrounds the cell plug CP. The drain select transistor, the plurality of memory cells and the source select transistor that are disposed along one cell plug CP may configure one cell string. Each memory block BLK may include a plurality of cell strings that correspond to a plurality of cell plugs CP.

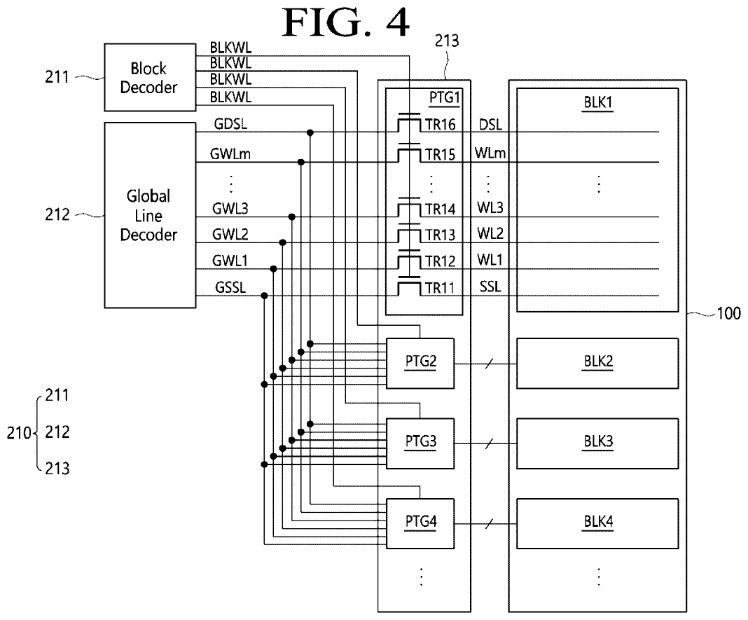

FIG. 4 is a diagram illustrating a row decoder according to an embodiment of the present disclosure.

Referring to FIG. 4, a row decoder 210 may include a block decoder 211, a global line decoder 212 and a pass transistor circuit 213.

The block decoder 211 may be connected to the pass transistor circuit 213 through block select signal lines BLKWL. The block decoder 211 may receive a row address from a control logic, and may output an activated block select signal to one of the block select signal lines BLKWL in response to the received row address.

The global line decoder 212 may be connected to the pass transistor circuit 213 through global row lines. The global row lines may include a global drain select line GDSL, a plurality of global word lines GWL1, GWL2, GWL3, . . . , GWLm and a global source select line GSSL. The global line decoder 212 may receive operating voltages from a voltage generator (not illustrated), and may output the operating voltages to the global row lines GDSL, GWL and GSSL in response to a control signal received from the control logic.

The pass transistor circuit 213 may include a plurality of pass transistor groups PTG1, PTG2, PTG3, PTG4, . . . corresponding to a plurality of memory blocks BLK1, BLK2, BLK3, BLK4, . . . , respectively.

Each pass transistor group PTG may be connected to a corresponding memory block BLK through a drain select line DSL, a plurality of word lines WL1, WL2, WL3, . . . , WLm and a source select line SSL. The pass transistor group PTG may be connected to the global line decoder 212 through the global drain select line GDSL, the plurality of global word lines GWL1, GWL2, GWL3, . . . , GWLm and the global source select line GSSL. The global drain select line GDSL, the plurality of global word lines GWL1, GWL2, GWL3, . . . , GWLm and the global source select line GSSL may be connected in common to the plurality of pass transistor groups PTG1, PTG2, PTG3, PTG4, . . . . That is to say, the plurality of pass transistor groups PTG1, PTG2, PTG3, PTG4, . . . may share the global drain select line GDSL, the plurality of global word lines GWL1, GWL2, GWL3, . . . , GWLm and the global source select line GSSL.

One pass transistor group selected among the pass transistor groups PTG1, PTG2, PTG3, PTG4, . . . , that is, a pass transistor group that receives an activated block select signal from the block decoder 211, may transmit operating voltages provided from the global line decoder 212 to a corresponding memory block BLK through the drain select line DSL, the Plurality of word lines WL1, WL2, WL3, . . . , WLm and the source select line SSL.

A first pass transistor group PTG1 may include a plurality of pass transistors TR11 to TR16.

The pass transistor TR11 may be connected between the global source select line GSSL and the source select line SSL. The pass transistors TR12 to TR15 may be connected between global word lines GWL1 to GWLm and word lines WL1 to WLm, respectively. The pass transistor TR16 may be connected between the global drain select line GDSL and the drain select line DSL.

The gate electrodes of the pass transistors TR11 to TR16 that are included in the first pass transistor group PTG1 may be connected in common to one block select signal line BLKWL. When an activated block select signal is provided to the first pass transistor group PTG1 through the block select signal line BLKWL, the pass transistors TR11 to TR16 included in the first pass transistor group PTG1 are turned on, and accordingly, operating voltages provided through the global source select line GSSL, the plurality of global word lines GWL1 to GWLm and the global drain select line GDSL may be transmitted to the first memory block BLK1 through the source select line SSL, the plurality of word lines WL1 to WLm and the drain select line DSL.

The description for the first pass transistor group PTG1 also applies similarly to the other pass transistor groups PTG2, PTG3, PTG4, . . . , and thus, repeated description will be omitted.

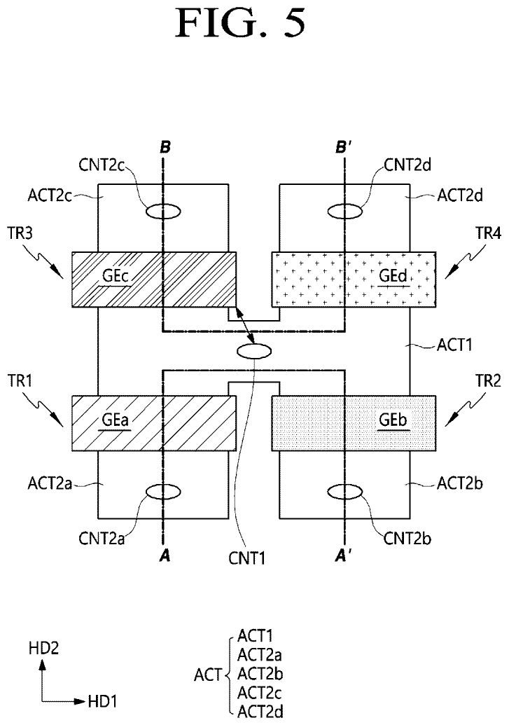

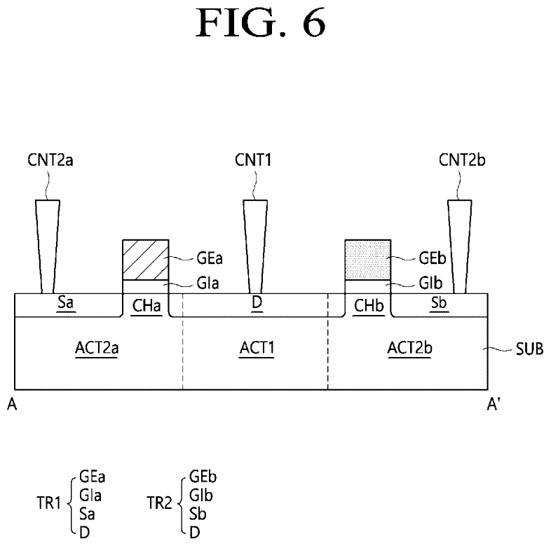

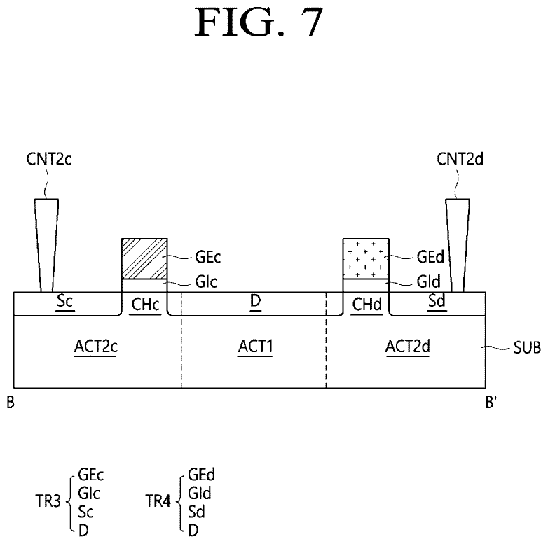

FIG. 5 is a plan view illustrating first, second, third and fourth pass transistors according to an embodiment of the present disclosure, FIG. 6 is a cross-sectional view taken along a line A-A′ of FIG. 5, and FIG. 7 is a cross-sectional view taken along a line B-B′ of FIG. 5.

Referring to FIGS. 5 to 7, as an isolation layer (not illustrated) is formed in a substrate SUB, an active region ACT may be defined. First, second, third and fourth pass transistors TR1, TR2, TR3 and TR4 may be configured in the active region ACT.

The substrate SUB may be composed of a semiconductor material. For example, the substrate SUB may include silicon (Si), germanium (Ge) or silicon germanium (SiGe).

In an embodiment, the active region ACT may, for example, have an H-shape. The active region ACT may include a common active region ACT1 and first, second, third and fourth protruding active regions ACT2a, ACT2b, ACT2c and ACT2d.

The common active region ACT1 may extend in the first horizontal direction HD1. In a plan view, the common active region ACT1 may have a rectangular shape with a dimension in the first horizontal direction HD1 larger than a dimension in the second horizontal direction HD2.

The first, second, third and fourth protruding active regions ACT2a, ACT2b, ACT2c and ACT2d may extend in the second horizontal direction HD2 at both ends of the common active region ACT1. The first and third protruding active regions ACT2a and ACT2c may extend in the second horizontal direction HD2 from both sides of one end of the common active region ACT1, and the second and fourth protruding active regions ACT2b and ACT2d may extend in the second horizontal direction HD2 from both sides of the other end of the common active region ACT1. Each of the first, second, third and fourth protruding active regions ACT2a, ACT2b, ACT2c and ACT2d may have a rectangular shape.

A first gate electrode GEa may be disposed over the first protruding active region ACT2a, and may cross the first protruding active region ACT2a in the first horizontal direction HD1. A second gate electrode GEb may be disposed over the second protruding active region ACT2b, and may cross the second protruding active region ACT2b in the first horizontal direction HD1. A third gate electrode GEc may be disposed over the third protruding active region ACT2c, and may cross the third protruding active region ACT2c in the first horizontal direction HD1. A fourth gate electrode GEd may be disposed over the fourth protruding active region ACT2d, and may cross the fourth protruding active region ACT2d in the first horizontal direction HD1. Each of the first, second, third and fourth gate electrodes GEa, GEb, GEc and GEd may have a rectangular shape. Although, the shape of the gate electrodes GEa, GEb, GEc and GEd is rectangular in the present disclosure, the shape of the gate electrodes is not limited thereto.

The first gate electrode GEa and the second gate electrode GEb may be disposed in a line in the first horizontal direction HD1, and the third gate electrode GEc and the fourth gate electrode GEd may be disposed in a line in the first horizontal direction HD1.

The first, second, third and fourth gate electrodes GEa, GEb, GEc and GEd may be spaced apart from the common active region ACT1 in the second horizontal direction HD2. The first protruding active region ACT2a may include a first section disposed on one side of the first gate electrode GEa that is opposite to the common active region ACT1 and a second section disposed on the other side of the first gate electrode GEa that faces the common active region ACT1. The second protruding active region ACT2b may include a third section disposed on one side of the second gate electrode GEb that is opposite to the common active region ACT1 and a fourth section disposed on the other side of the second gate electrode GEb that faces the common active region ACT1. The third protruding active region ACT2c may include a fifth section disposed on one side of the third gate electrode GEc that is opposite to the common active region ACT1 and a sixth section disposed on the other side of the third gate electrode GEc that faces the common active region ACT1. The fourth protruding active region ACT2d may include a seventh section disposed on one side of the fourth gate electrode GEd that is opposite to the common active region ACT1 and an eighth section disposed on the other side of the fourth gate electrode GEd that faces the common active region ACT1.

A drain region D may be defined as a first impurity is doped into the common active region ACT1, the second section of the first protruding active region ACT2a, the fourth section of the second protruding active region ACT2b, the sixth section of the third protruding active region ACT2c and the eighth section of the fourth protruding active region ACT2d. The first impurity may be an n-type impurity. The n-type impurity may include phosphorus (P), arsenic (As) and antimony (Sb).

As the first impurity is doped into the first section of the first protruding active region ACT2a, a first source region Sa may be defined. As the first impurity is doped into the third section of the second protruding active region ACT2b, a second source region Sb may be defined. As the first impurity is doped into the fifth section of the third protruding active region ACT2c, a third source region Sc may be defined. As the first impurity is doped into the seventh section of the fourth protruding active region ACT2d, a fourth source region Sd may be defined.

A first gate insulating layer GIa may be disposed between the first gate electrode GEa and the substrate SUB, a second gate insulating layer GIb may be disposed between the second gate electrode GEb and the substrate SUB, a third gate insulating layer GIc may be disposed between the third gate electrode GEc and the substrate SUB, and a fourth gate insulating layer GId may be disposed between the fourth gate electrode GEd and the substrate SUB.

The first gate electrode GEa, the first gate insulating layer GIa, the first source region Sa and the drain region D may configure the first pass transistor TR1. The second gate electrode GEb, the second gate insulating layer GIb, the second source region Sb and the drain region D may configure the second pass transistor TR2. The third gate electrode GEc, the third gate insulating layer GIc, the third source region Sc and the drain region D may configure the third pass transistor TR3. The fourth gate electrode GEd, the fourth gate insulating layer GId, the fourth source region Sd and the drain region D may configure the fourth pass transistor TR4. The first, second, third and fourth pass transistors TR1, TR2, TR3 and TR4 may share the one drain region D.

The first pass transistor TR1 may be configured in the common active region ACT1 and the first protruding active region ACT2a. The second pass transistor TR2 may be configured in the common active region ACT1 and the second protruding active region ACT2b. The third pass transistor TR3 may be configured in the common active region ACT1 and the third protruding active region ACT2c. The fourth pass transistor TR4 may be configured in the common active region ACT1 and the fourth protruding active region ACT2d. The first, second, third and fourth pass transistors TR1, TR2, TR3 and TR4 may share the common active region ACT1.

A first channel region CHa of the first pass transistor TR1 may be disposed in the first protruding active region ACT2a that overlaps the first gate electrode GEa in the vertical direction VD. A second channel region CHb of the second pass transistor TR2 may be disposed in the second protruding active region ACT2b that overlaps the second gate electrode GEb in the vertical direction VD. A third channel region CHc of the third pass transistor TR3 may be disposed in the third protruding active region ACT2c that overlaps the third gate electrode GEc in the vertical direction VD. A fourth channel region CHd of the fourth pass transistor TR4 may be disposed in the fourth protruding active region ACT2d that overlaps the fourth gate electrode GEd in the vertical direction VD.

A first contact CNT1 may be connected to the drain region D. The first contact CNT1 might not overlap the first, second, third and fourth protruding active regions ACT2a, ACT2b, ACT2c and ACT2d in the second horizontal direction HD2. The first contact CNT1 may be spaced apart from the first, second, third and fourth channel regions CHa, CHb, CHc and CHd in diagonal directions that intersect the first horizontal direction HD1 and the second horizontal direction HD2. The first contact CNT1 may be connected to a global line decoder through a global row line, and can pass an operating voltage provided by the global line decoder to the drain region D.

Because the first contact CNT1 is spaced apart from the first, second, third and fourth channel regions CHa, CHb, CHc and CHd in the diagonal directions, compared to a case where a first contact is spaced apart from channel regions in the second horizontal direction HD2, the dimension of the drain region D in the second horizontal direction HD2 may be reduced without narrowing the spacing between the first contact CNT1 and the first, second, third and fourth channel regions CHa, CHb, CHc and CHd. In other words, while preventing the breakdown voltage (BVDSS) of a pass transistor from degrading due to the influence of a high voltage applied to the first contact CNT1, the dimension of the drain region D in the second horizontal direction HD2 may be reduced, thereby reducing areas occupied by the first, second, third and fourth pass transistors TR1, TR2, TR3 and TR4.

Second, third, fourth and fifth contacts CNT2a, CNT2b, CNT2c and CNT2d may be connected to the first, second, third and fourth source regions Sa, Sb, Sc and Sd, respectively. The second, third, fourth and fifth contacts CNT2a, CNT2b, CNT2c and CNT2d may be connected to a memory cell array through row lines. The second, third, fourth and fifth contacts CNT2a, CNT2b, CNT2c and CNT2d may be connected to different memory blocks.

For example, the second contact CNT2a may be connected to a first memory block. When the first pass transistor TR1 is turned on, an operating voltage applied to the drain region D through the first contact CNT1 may be transmitted to the first memory block through the first source region Sa, the second contact CNT2a and a row line.

The third contact CNT2b may be connected to a second memory block, the fourth contact CNT2c may be connected to a third memory block, and the fifth contact CNT2d may be connected to a fourth memory block. The description for the second contact CNT2a also applies similarly to the third, fourth and fifth contacts CNT2b, CNT2c and CNT2d, and thus, repeated description will be omitted.

The embodiment described with reference to FIGS. 5 to 7 illustrates a case where the common active region ACT1 extends in the first horizontal direction HD1 perpendicular to the second horizontal direction HD2 in that memory blocks are arranged and the first, second, third and fourth protruding active regions ACT2a, ACT2b, ACT2c and ACT2d extend from the common active region ACT1 in the second horizontal direction HD2, but the present disclosure is not limited thereto. The extending direction of the common active region ACT1 and the extending direction of the first, second, third and fourth protruding active regions ACT2a, ACT2b, ACT2c and ACT2d may be changed with each other.

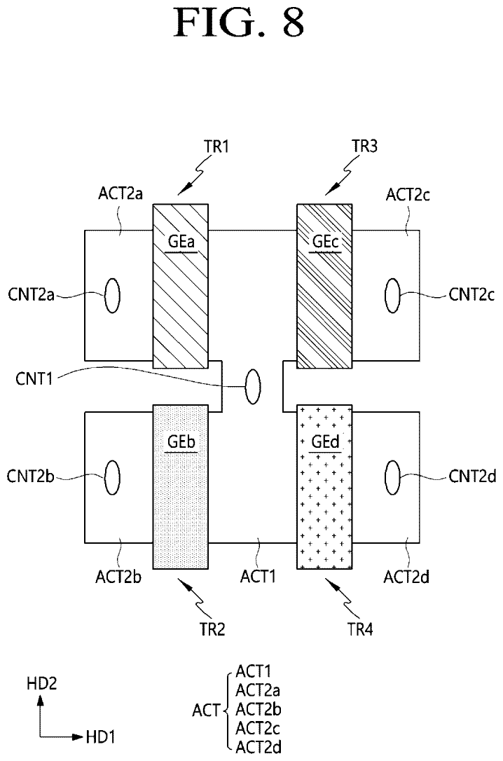

FIG. 8 is a plan view illustrating first, second, third and fourth pass transistors according to an embodiment of the present disclosure.

Referring to FIG. 8, a common active region ACT1 may extend in the second horizontal direction HD2, and first, second, third and fourth protruding active regions ACT2a, ACT2b, ACT2c and ACT2d may extend in the first horizontal direction HD1 at both ends of the common active region ACT1.

In a plan view, the common active region ACT1 may have a rectangular shape with a dimension in the second horizontal direction HD2 larger than a dimension in the first horizontal direction HD1.

The first and third protruding active regions ACT2a and ACT2c may extend in the first horizontal direction HD1 from both sides of one end of the common active region ACT1, and the second and fourth protruding active regions ACT2b and ACT2d may extend in the first horizontal direction HD1 from both sides of the other end of the common active region ACT1.

A first gate electrode GEa may be disposed on the first protruding active region ACT2a, and may cross the first protruding active region ACT2a in the second horizontal direction HD2. A second gate electrode GEb may be disposed on the second protruding active region ACT2b, and may cross the second protruding active region ACT2b in the second horizontal direction HD2. A third gate electrode GEc may be disposed on the third protruding active region ACT2c, and may cross the third protruding active region ACT2c in the second horizontal direction HD2. A fourth gate electrode GEd may be disposed on the fourth protruding active region ACT2d, and may cross the fourth protruding active region ACT2d in the second horizontal direction HD2.

The first, second, third and fourth gate electrodes GEa, GEb, GEc and GEd may be spaced apart from the common active region ACT1 in the first horizontal direction HD1. The first gate electrode GEa and the second gate electrode GEb may be disposed in a line in the second horizontal direction HD2, and the third gate electrode GEc and the fourth gate electrode GEd may be disposed in a line in the second horizontal direction HD2. A first contact CNT1 might not overlap the first, second, third and fourth protruding active regions ACT2a, ACT2b, ACT2c and ACT2d in the first horizontal direction HD1. The first contact CNT1 may be spaced apart from the first, second, third and fourth channel regions in diagonal directions that intersect the first horizontal direction HD1 and the second horizontal direction HD2. Second, third, fourth and fifth contacts CNT2a, CNT2b, CNT2c and CNT2d may be connected to the first, second, third and fourth source regions, respectively. The second, third, fourth and fifth contacts CNT2a, CNT2b, CNT2c and CNT2d may be connected to a memory cell array through row lines. The second, third, fourth and fifth contacts CNT2a, CNT2b, CNT2c and CNT2d may be connected to different memory blocks.

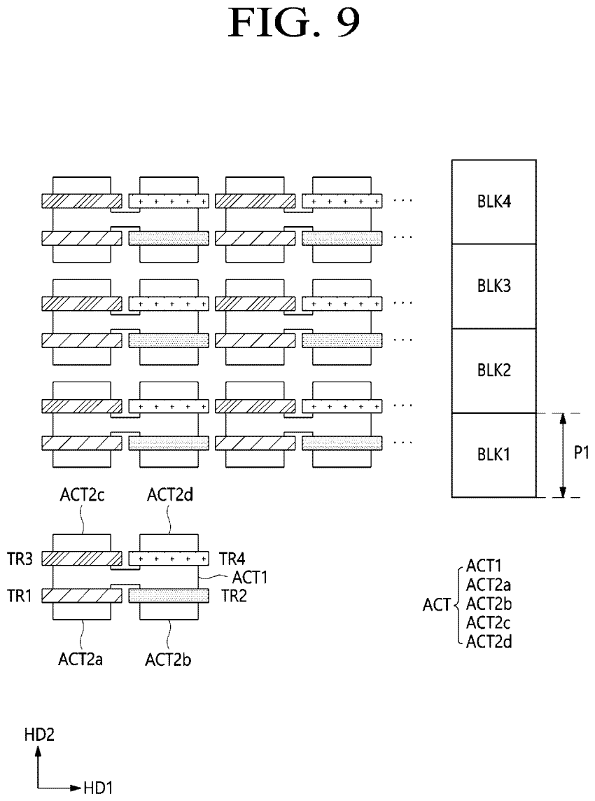

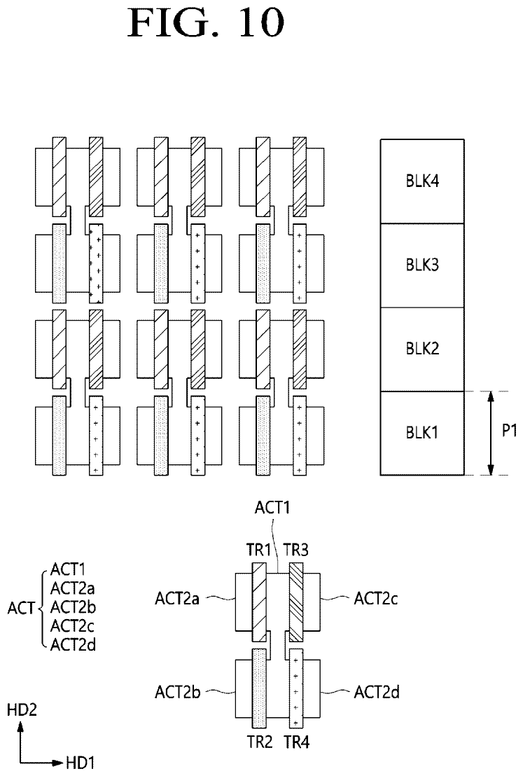

FIGS. 9 and 10 are plan views each illustrating a part of a pass transistor circuit according to each of embodiments of the present disclosure. FIGS. 9 and 10 illustrate first, second, third and fourth pass transistors TR1, TR2, TR3 and TR4 connected to first, second, third and fourth memory blocks BLK1, BLK2, BLK3 and BLK4 among pass transistors included in the pass transistor circuit.

Referring to FIGS. 9 and 10, the first, second, third and fourth memory blocks BLK1, BLK2, BLK3 and BLK4 may be disposed in a line in the second horizontal direction HD2. The dimension of each of the first, second, third and fourth memory blocks BLK1, BLK2, BLK3 and BLK4 in the second horizontal direction HD2 may be P1. P1 may be defined as a one-block pitch.

Active regions ACT each having an H shape may be disposed in three stages within a four-block pitch, and first, second, third and fourth pass transistors TR1, TR2, TR3 and TR4 may be configured in each active region ACT.

The active region ACT and the first, second, third and fourth pass transistors TR1, TR2, TR3 and TR4 of FIG. 9 have the same structure as that described above with reference to FIG. 5. The active region ACT and the first, second, third and fourth pass transistors TR1, TR2, TR3 and TR4 of FIG. 10 may have the same structure as that described above with reference to FIG. 8.

First, second, third and fourth pass transistors TR1, TR2, TR3 and TR4 connected to the first, second, third and fourth memory blocks BLK1, BLK2, BLK3 and BLK4 may be configured within the four-block pitch (P1×4).

In order to reduce the size of a memory device, not only the block pitch P1 but also an area occupied by a plurality of pass transistors should be reduced. In the embodiments of the present disclosure, the active region ACT is configured to include the common active region ACT1 and the first, second, third and fourth protruding active regions ACT2a, ACT2b, ACT2c and ACT2d that extend in a direction perpendicular to the extending direction of the common active region ACT1 at edges of the common active region ACT1, and four pass transistors are configured to share the common active region ACT1. Therefore, while not causing degradation in the characteristics of the pass transistors, an area occupied by the pass transistors may be reduced to contribute to high integration of a memory device.

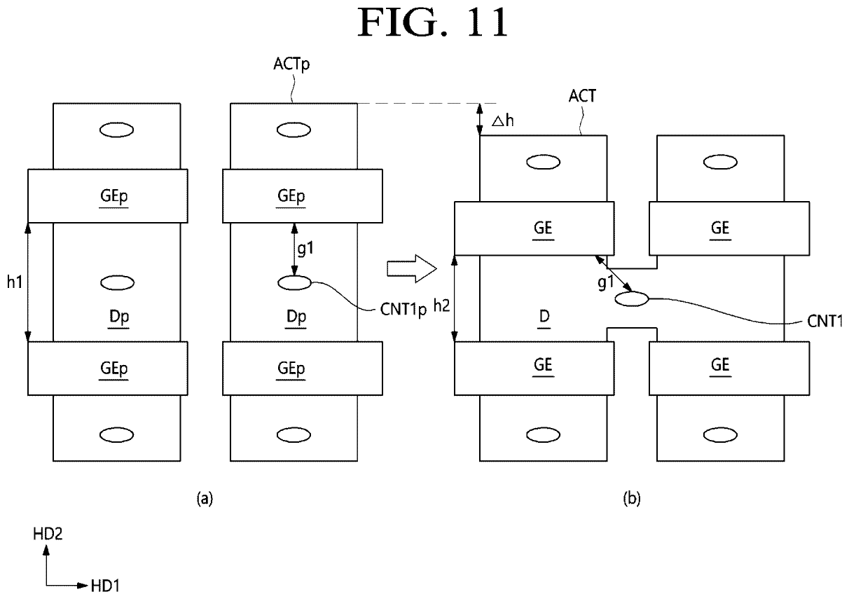

FIGS. 11 to 13 are views illustrating effects of the present disclosure. In FIGS. 11 to 13, views (a) illustrates a comparative example that is in contrast to the present disclosure, and views (b) illustrates an embodiment of the present disclosure.

Referring to FIG. 11, in the present disclosure, an active region ACT is configured in an H shape, and a first contact CNT1 is spaced apart, in a diagonal direction, from a channel region that is the active region ACT below a gate electrode GE. On the other hand, in the comparative example, an active region ACTp is configured in a straight line (rectangular) shape, and a first contact CNT1p is spaced apart from a channel region in the second horizontal direction HD2.

When the spacing between a first contact and a channel region is the same as g1 in both the present disclosure and the comparative example, the dimension in the second horizontal direction HD2 of a drain region D in the present disclosure has a smaller size than the dimension in the second horizontal direction HD2 of a drain region Dp in the comparative example. In the comparative example, the dimension in the second horizontal direction HD2 of the drain region Dp is h1, and in the present disclosure, the dimension in the second horizontal direction HD2 of the drain region D is h2, and h2 is smaller than h1 by Δh.

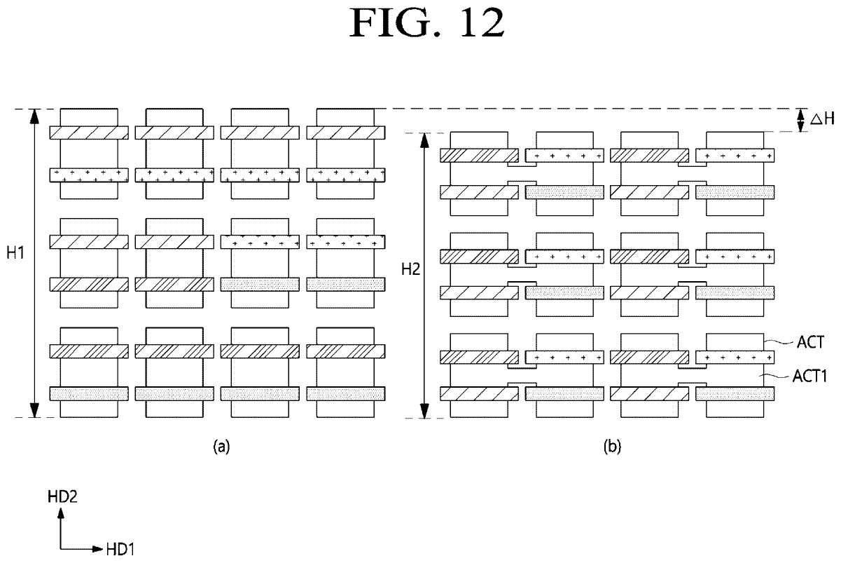

Referring to FIG. 12, when a common active region ACT1 extends in the first horizontal direction HD1, the dimension in the second horizontal direction HD2 of a region occupied by 24 pass transistors has a smaller size in the present disclosure than in the comparative example.

The size of the dimension in the second horizontal direction HD2 of the region occupied by 24 pass transistors is H1 in the comparative example and H2 in the present disclosure, and H2 has a size smaller than H1 by ΔH.

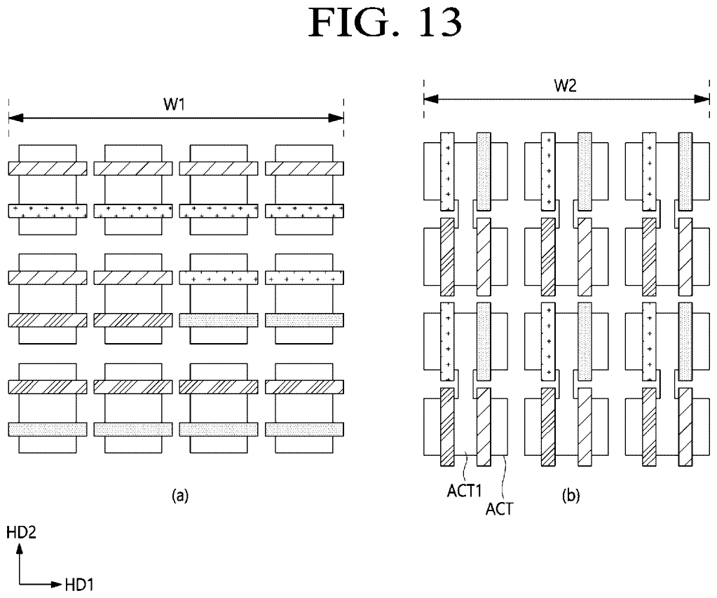

Referring to FIG. 13, when a common active region ACT1 extends in the second horizontal direction HD2, the dimension in the first horizontal direction HD1 of a region occupied by 24 pass transistors has a smaller size in the present disclosure than in the comparative example.

The size of the dimension in the first horizontal direction HD1 of the region occupied by 24 pass transistors is W1 in the comparative example and W2 in the present disclosure, and W2 is smaller than W1.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A memory device comprising:
a substrate defined with an H-shaped active region including a common active region that extends in a first horizontal direction and first, second, third and fourth protruding active regions that extend from edges of the common active region in a second horizontal direction perpendicular to the first horizontal direction;
a first pass transistor having a first gate electrode that is disposed over the first protruding active region;
a second pass transistor having a second gate electrode that is disposed over the second protruding active region;
a third pass transistor having a third gate electrode that is disposed over the third protruding active region; and
a fourth pass transistor having a fourth gate electrode that is disposed over the fourth protruding active region.

2. The memory device according to claim 1, wherein the first, second, third and fourth pass transistors are connected to different memory blocks.

3. The memory device according to claim 1, wherein the first, second, third and fourth gate electrodes are spaced apart from the common active region in the second horizontal direction.

4. The memory device according to claim 1, wherein
the first gate electrode and the second gate electrode are disposed in a line in the first horizontal direction, and
the third gate electrode and the fourth gate electrode are disposed in a line in the first horizontal direction.

5. The memory device according to claim 1, further comprising:
a first contact connected to the common active region,
wherein the first protruding active region includes a first channel region that vertically overlaps the first gate electrode,
wherein the second protruding active region includes a second channel region that vertically overlaps the second gate electrode,
wherein the third protruding active region includes a third channel region that vertically overlaps the third gate electrode,
wherein the fourth protruding active region includes a fourth channel region that vertically overlaps the fourth gate electrode, and
wherein, in a plan view, the first contact is spaced apart from the first, second, third and fourth channel regions in diagonal directions intersecting the first horizontal direction and the second horizontal direction.

6. The memory device according to claim 1, further comprising:
a first memory block connected to the first pass transistor;
a second memory block connected to the second pass transistor;
a third memory block connected to the third pass transistor; and
a fourth memory block connected to the fourth pass transistor,
wherein the substrate and the first, second, third and fourth pass transistors are included in a first semiconductor layer, and
wherein the first, second, third and fourth memory blocks are included in a second semiconductor layer that vertically overlaps the first semiconductor layer.

7. The memory device according to claim 1, further comprising:
a first memory block connected to the first pass transistor;
a second memory block connected to the second pass transistor;
a third memory block connected to the third pass transistor; and
a fourth memory block connected to the fourth pass transistor,
wherein the substrate and the first, second, third and fourth pass transistors are included in a first wafer, and
wherein the first, second, third and fourth memory blocks are included in a second wafer that is bonded to the first wafer.

8. A memory device comprising:
a plurality of memory blocks arranged in a first horizontal direction;
a substrate defined with an H-shaped active region including a common active region that extends in the first horizontal direction and first, second, third and fourth protruding active regions that extend from edges of the common active region in a second horizontal direction perpendicular to the first horizontal direction;
a first pass transistor having a first gate electrode that is disposed over the first protruding active region;
a second pass transistor having a second gate electrode that is disposed over the second protruding active region;
a third pass transistor having a third gate electrode that is disposed over the third protruding active region; and
a fourth pass transistor having a fourth gate electrode that is disposed over the fourth protruding active region.

9. The memory device according to claim 8, wherein
the substrate and the first, second, third and fourth pass transistors are included in a first semiconductor layer, and
the plurality of memory blocks are included in a second semiconductor layer that vertically overlaps the first semiconductor layer.

10. The memory device according to claim 8, wherein
the substrate and the first, second, third and fourth pass transistors are included in a first wafer, and
the plurality of memory blocks are included in a second wafer that is bonded to the first wafer.

11. The memory device according to claim 8, wherein the plurality of memory blocks comprise:
a plurality of electrode layers and a plurality of interlayer insulating layers vertically alternately stacked on a source plate that vertically overlaps the substrate; and
a plurality of cell plugs extending to the source plate by vertically passing through the plurality of electrode layers and the plurality of interlayer insulating layers.

12. A memory device comprising:
a plurality of memory blocks arranged in a first horizontal direction;
a substrate defined with an H-shaped active region including a common active region that extends in a second horizontal direction perpendicular to the first horizontal direction and first, second, third and fourth protruding active regions that extend from edges of the common active region in the first horizontal direction;
a first pass transistor having a first gate electrode that is disposed over the first protruding active region;
a second pass transistor having a second gate electrode that is disposed over the second protruding active region;
a third pass transistor having a third gate electrode that is disposed over the third protruding active region; and
a fourth pass transistor having a fourth gate electrode that is disposed over the fourth protruding active region.

13. The memory device according to claim 12, wherein
the substrate and the first, second, third and fourth pass transistors are included in a first semiconductor layer, and
the plurality of memory blocks are included in a second semiconductor layer that vertically overlaps the first semiconductor layer.

14. The memory device according to claim 12, wherein
the substrate and the first, second, third and fourth pass transistors are included in a first wafer, and
the plurality of memory blocks are included in a second wafer that is bonded to the first wafer.

15. The memory device according to claim 12, wherein the plurality of memory blocks comprise:
a plurality of electrode layers and a plurality of interlayer insulating layers vertically alternately stacked on a source plate that vertically overlaps the substrate; and
a plurality of cell plugs extending to the source plate by vertically passing through the plurality of electrode layers and the plurality of interlayer insulating layers.

16. The memory device according to claim 8, further comprising:
a first contact connected to the common active region,
wherein the first protruding active region includes a first channel region that vertically overlaps the first gate electrode,
wherein the second protruding active region includes a second channel region that vertically overlaps the second gate electrode,
wherein the third protruding active region includes a third channel region that vertically overlaps the third gate electrode,
wherein the fourth protruding active region includes a fourth channel region that vertically overlaps the fourth gate electrode, and
wherein the first, second, third and fourth pass transistors share one drain region.

17. The memory device according to claim 12, further comprising:
a first contact connected to the common active region,
wherein the first protruding active region includes a first channel region that vertically overlaps the first gate electrode,
wherein the second protruding active region includes a second channel region that vertically overlaps the second gate electrode,
wherein the third protruding active region includes a third channel region that vertically overlaps the third gate electrode,
wherein the fourth protruding active region includes a fourth channel region that vertically overlaps the fourth gate electrode, and
wherein, in a plan view, the first contact is spaced apart from the first, second, third and fourth channel regions in diagonal directions intersecting the first horizontal direction and the second horizontal direction.

18. The memory device according to claim 17, further comprising:
a second contact connected to a first source region,
a third contact connected to a second source region,
a fourth contact connected to a third source region,
a fifth contact connected to a fourth source region,
wherein the second, third, fourth and fifth contacts are connected to different memory blocks.
